(19) United States
(12) Patent Application Publication
(10) Pub. No.: US 2025/0089351 A1
(43) Pub. Date: Mar. 13, 2025

(54) SEMICONDUCTOR DEVICE AND SEMICONDUCTOR MODULE

(71) Applicant: FUJI ELECTRIC CO., LTD., Kanagawa (JP)

(72) Inventor: Soichi YOSHIDA, Matsumoto-city (JP)

(21) Appl. No.: 18/959,659

(22) Filed: Nov. 26, 2024

Related U.S. Application Data
(63) Continuation of application No. PCT/JP2023/039556, filed on Nov. 2, 2023.

(30) Foreign Application Priority Data
Dec. 22, 2022 (JP) 2022-205472

(51) Int. Cl. H01L 27/06; H01L 23/31; H01L 29/739

(52) U.S. Cl. CPC H10D 84/811; H01L 23/3171; H10D 12/481

(57) ABSTRACT

Provided is a semiconductor device, including: a semiconductor substrate including an active portion provided with a transistor portion; an emitter electrode provided above a front surface of the semiconductor substrate; and a protective film provided above the emitter electrode, where the active portion includes: an emitter region of a first conductivity type provided on the front surface of the semiconductor substrate; a contact region of a second conductivity type; and a plurality of trench portions, where the emitter electrode includes an exposed portion not covered by the protective film, and where the active portion includes: in a region in which the exposed portion is provided, a first region; and a second region provided at an outer circumference of the first region and having a channel density lower than that of the first region.

The contents of the following patent application(s) are incorporated herein by reference:
NO. 2022-205472 filed in JP on Dec. 22, 2022
NO. PCT/JP2023/039556 filed in WO on Nov. 2, 2023.

### BACKGROUND

### 1. Technical Field

The present invention relates to a semiconductor device and a semiconductor module.

### 2. Related Art

Patent Document 1 discloses that solder bonding is used to electrically connect a device electrode and a lead terminal with a coupling conductor.

### PRIOR ART DOCUMENTS

### Patent Document

Patent Document 1: Japanese Patent Application Publication No. 2009-38140

### BRIEF DESCRIPTION OF THE DRAWINGS

FIG. 1 is a top view showing an example of a semiconductor device 100 according to an exemplary embodiment.

FIG. 2 is an example of an enlarged view of the active portion 120.

FIG. 3 is a diagram showing an example of a cross section a-a in FIG. 2.

FIG. 4 is a diagram showing an example of the configurations of a first region 121 and a second region 122.

FIG. 5 is a top view showing an example of the mesa portion 60.

FIG. 6 is another example of an enlarged view of the active portion 120.

FIG. 7 is a diagram showing an example of a cross section b-b in FIG. 6.

FIG. 8 is a diagram showing an exemplary arrangement of the transistor portion 70 and the diode portion 80.

FIG. 9 is a top view showing an example of a semiconductor module 300 according to an exemplary embodiment.

FIG. 10 is a side view of the semiconductor substrate 10 mounted on a packaging substrate 200.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the +Z axis direction and the −Z axis direction are directions opposite to each other. When the Z axis direction is described without describing the signs, it means that the direction is parallel to the +Z axis and the −Z axis. As used herein, when seen from the +Z axis direction, it may also be referred to “as seen from above”.

In the present specification, a case where a term such as “same” or “equal” is mentioned may include a case where an error due to a variation in manufacturing or the like is included. The error is, for example, within 10%.

In the present specification, a conductivity type of a doping region where doping has

been carried out with an impurity is described as a P type or an N type. Note that conductivity types of respective doping regions may be of opposite polarities, respectively. Further, in the present specification, a description of a P+ type or an N+ type means a higher doping concentration than that of the P type or the N type, and a description of a P− type or an N− type means a lower doping concentration than that of the P type or the N type.

In the present specification, the doping concentration refers to a concentration of an impurity activated as a donor or an acceptor. Herein, in some cases, a concentration difference between a donor and an acceptor may be a higher concentration of the majority of the donor or the acceptor. The concentration difference can be measured by the capacitance-voltage profiling method (CV method). Also, a carrier concentration measured by Spread Resistance (SR) measurement method may be a concentration of a donor or an acceptor. Furthermore, in a case where a concentration distribution of a donor or an acceptor has a peak, the peak value may be a concentration of a donor or acceptor in the region. For example, when a concentration of a donor or an acceptor in a region where the donor or the acceptor exists is approximately uniform, the average value of a concentration of a donor or an acceptor in the region may be a donor or acceptor concentration.

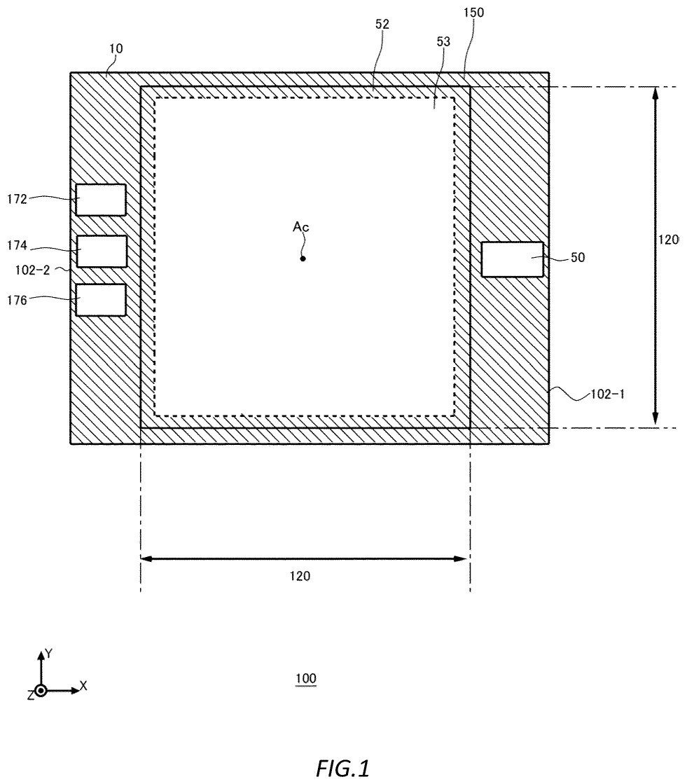

FIG. 1 is a top view showing an example of a semiconductor device 100 according to an exemplary embodiment. The semiconductor device 100 includes a semiconductor substrate 10. The semiconductor substrate 10 is a substrate which is formed of a semiconductor material such as silicon or a compound semiconductor. The semiconductor substrate 10 has an end side 102 in the top view. The semiconductor substrate 10 of the present example includes two sets of end sides 102 facing each other in the top view. FIG. 1 shows a pair of a first end side 102-1 and a second end side 102-2 facing each other. In FIG. 1, a direction that is parallel to the first end side 102-1 and the second end side 102-2 is denoted as a Y axis direction, and a direction that is perpendicular to the first end side 102-1 and the second end side 102-2 is denoted as an X axis direction.

The semiconductor substrate 10 is provided with an active portion 120. The active portion 120 is a region where a main current flows in the depth direction between the front surface and a back surface of the semiconductor substrate 10 in a case where the semiconductor device 100 is controlled to be in an on-state. In the present example, a region corresponding to an emitter electrode 52 is defined as the active portion 120. The active portion 120 may be provided with a transistor portion including a transistor device such as an IGBT (insulated gate bipolar transistor.) The active portion 120 may also be provided with a diode portion including a diode device such as an FWD (freewheeling diode.)

The semiconductor device 100 includes the emitter electrode 52 and a pad 50 provided above a front surface of the semiconductor substrate 10. The emitter electrode 52 and the pad 50 are electrodes including a metal such as aluminum. A dielectric film is provided between the emitter electrode 52 and the pad 50, and the semiconductor substrate 10. The emitter electrode 52 and the pad 50 are connected to the semiconductor substrate 10 via a contact hole provided in the dielectric film. In FIG. 1, the dielectric film and the contact hole are omitted.

The emitter electrode 52 is arranged above the active portion 120. The emitter electrode 52 is connected to the active portion 120 via the contact hole described above. The emitter electrode 52 includes an exposed portion 53 not covered by a protective film which will be described below. The exposed portion 53 is a region including a center Ac of the active portion 120. The center Ac of the active portion 120 is the geometric center of gravity of the active portion 120 in a top view. A lead frame which will be described below is arranged on an upper surface of the exposed portion 53. The emitter electrode 52 is electrically connected to the lead frame and a predetermined emitter voltage is applied thereto.

The emitter electrode 52 is formed of a material including a metal. For example, at least a part of a region of the emitter electrode 52 is formed of aluminum or an aluminum-silicon alloy. The emitter electrode 52 may have a barrier metal formed of titanium, a titanium compound, or the like below a region formed of aluminum or the like. The emitter electrode 52 may further include a plug formed of tungsten or the like filled in the contact hole to be in contact with the barrier metal and aluminum or the like. A plating layer may also be provided on an upper surface of the emitter electrode 52. The plating layer may be a metal material such as nickel and gold different from the emitter electrode 52.

The pad 50 is a gate pad, for example. The emitter electrode 52 and the pad 50 are provided to be separated from each other in a top view. A wire or the like is connected to an upper surface of the pad 50 through which a predetermined gate voltage is applied. The gate voltage applied to the pad 50 is supplied to the transistor portion of the active portion 120 through a gate runner or the like which will be described below. The pad 50 of the present example is provided in the vicinity of the first end side 102-1.

In addition to the configuration of the semiconductor device 100, an anode pad 174, a cathode pad 176 and a current detection pad 172 are provided. The semiconductor device 100 may further include a current sensor having a structure similar to the transistor portion of the semiconductor substrate to simulate an operation of the transistor portion and detect a current flowing between the front surface and the back surface of the semiconductor substrate. The anode pad 174, the cathode pad 176 and the current detection pad 172 of the present example are provided in the vicinity of the second end side 102-2, and a region in which these pads are provided may be referred to as a pad region.

The semiconductor device 100 includes a protective film 150 provided above the front surface of the semiconductor substrate 10. The protective film 150 is formed of polyimide or the like and covers the front surface side of the semiconductor substrate 10 to protect the front surface device structure. FIG. 1 shows a region in which the protective film 150 is provided hatched with diagonal lines. The protective film 150 includes an opening portion corresponding to the exposed portion 53 on the emitter electrode 52. The protective film 150 may also include opening portions at positions corresponding to the pad 50, the anode pad 174, the cathode pad 176 and the current detection pad 172 and the pad region.

In FIG. 1, additional active portions may also be provided above and below the pad 50 and the pad region (in the +Y axis direction and the −Y axis direction.)

In this case, the emitter electrode 52 may be provided to extend above the additional active portion.

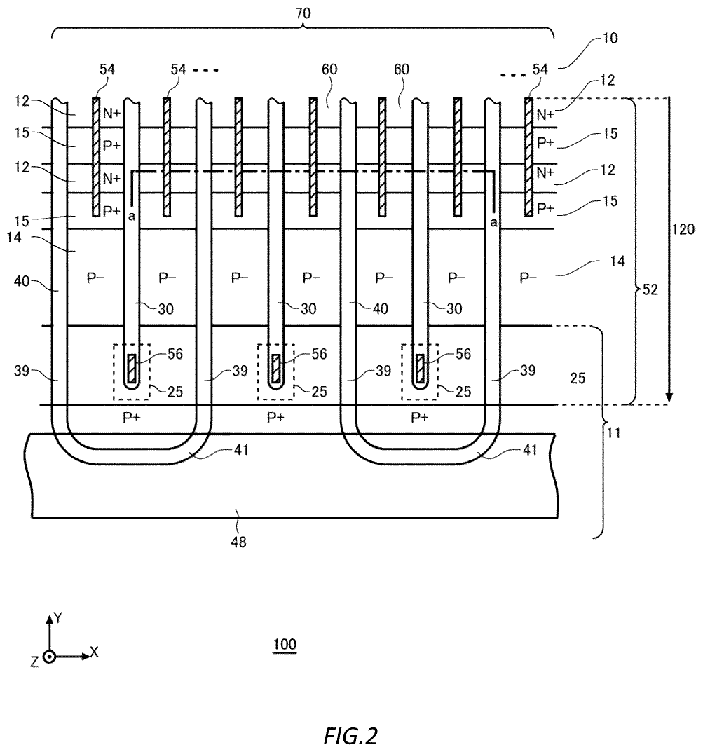

FIG. 2 is an example of an enlarged view of the active portion 120. The active portion 120 of the present example includes the transistor portion 70. FIG. 2 shows a region of the active portion 120 around an end portion at the side in the −Y axis direction.

The semiconductor device 100 may include a gate runner 48 arranged to surround the active portion 120 in a top view. The gate runner 48 is a wiring formed of a conductive material such as polysilicon with impurity added thereto, or metal. The gate runner 48 supplies a gate voltage applied to the gate pad 50 to the transistor portion 70. The gate runner 48 may be arranged above a well region 11 which will be described below.

The semiconductor device 100 of the present example includes a gate trench portion 40, a dummy trench portion 30, a well region 11, an emitter region 12, a base region 14, and a contact region 15 provided inside the front surface side of the semiconductor substrate 10.

FIG. 2 shows a range where the emitter electrode 52 is provided. The emitter electrode 52 of the present example is provided in a range which does not overlap with the gate runner 48, but may overlap with the gate runner 48. In this case, a dielectric film is provided between the emitter electrode 52 and the gate runner 48. An interlayer dielectric film is provided between the emitter electrode 52 and the front surface of the semiconductor substrate 10, although it is omitted in FIG. 2. The interlayer dielectric film of the present example is provided with a contact holes 56 and a contact hole 54 penetrating the interlayer dielectric film.

The emitter electrode 52 is in contact with the emitter region 12, the contact region 15, and the base region 14 on the front surface of the semiconductor substrate 10, through the contact hole 54.

In addition, the emitter electrode 52 is connected to a dummy conductive portion in the dummy trench portion 30 via the contact hole 56. Between the emitter electrode 52 and the dummy conductive portion, a connecting portion 25 formed of a conductive material such as polysilicon doped with the impurities may be provided. The connecting portion 25 is provided above the front surface of the semiconductor substrate 10. A dielectric film is provided between the connecting portion 25 and the front surface of the semiconductor substrate 10.

A dielectric film is provided between the gate runner 48 and the front surface of the semiconductor substrate 10. The gate runner 48 is connected to a gate conductive portion in the gate trench portion 40 on the front surface of the semiconductor substrate 10. The gate runner 48 is not connected to the dummy conductive portion in the dummy trench portion 30. The gate runner 48 of the present example is provided to overlap with an edge portion 41 of the gate trench portion 40. The edge portion 41 is an end portion closest to the gate runner 48 in the gate trench portion 40. At the edge portion 41 of the gate trench portion 40, the gate conductive portion is exposed to the front surface of the semiconductor substrate 10 to be in contact with the gate runner 48.

One or more gate trench portions 40 and one or more dummy trench portions 30 are arrayed at a predetermined interval along a predetermined array direction in a region of the transistor portion 70. In the present example, the array direction (also referred to as a trench array direction) is the X axis direction. In the present example, one or more gate trench portions 40 and one or more dummy trench portions 30 may be provided alternately along the array direction.

The gate trench portion 40 of the present example may have two extending portions 39 (a straight portion of a trench along an extending direction) that extends along an extending direction (also referred to as a trench extending direction) perpendicular to the array direction, and the edge portion 41 that connects the two extending portions 39. The extending direction of the present example is the Y axis direction. At least a part of the edge portion 41 is preferably provided in a curved shape. The end portions, which are the ends of the straight shape along the extending direction, of the two extending portions 39 of the gate trench portion 40 are connected by the edge portion 41, so that electric field strength at the end portions of the extending portions 39 can be reduced.

The dummy trench portion 30 of the present example is provided between the respective extending portions 39 of the gate trench portion 40. These dummy trench portions 30 may have a straight shape to extend in the extending direction.

The emitter electrode 52 is provided above the gate trench portion 40, the dummy trench portion 30, the well region 11, the emitter region 12, the base region 14, and the contact region 15. The well region 11 is provided in a predetermined range to be apart from the contact hole 54. A diffusion depth of the well region 11 may be greater than a depth of the gate trench portion 40 and the dummy trench portion 30. The end portions of the gate trench portion 40 and the dummy trench portion 30 in the extending direction is provided in the well region 11.

The mesa portion 60 interposed between the adjacent trench portions is provided with the base region 14. A mesa portion refers to a portion of the semiconductor substrate 10 that is interposed between the trench portions and a region of the front surface side with respect to the deepest bottom portion of the trench portion. The base region 14 is of the second conductivity type and has a doping concentration lower than the well region 11. The base region 14 of this example is of a P− type, and the well region 11 is of a P+ type.

The contact region 15 of the second conductivity type having a doping concentration higher than that of the base region 14 is provided on the upper surface of the base region 14 of the mesa portion 60. The contact region 15 of the present example is of the P+ type. The well region 11 may be provided to be apart from the contact region 15 arranged outermost in the trench extending direction (the −Y axis direction in FIG. 2) from among the contact regions 15 toward a direction of the gate runner 48. In addition, in the transistor portion 70, the emitter regions 12 of the first conductivity type having a doping concentration higher than that of a drift region 18 which will be described below are provided selectively above the base region 14. The emitter region 12 of the present example is of an N+ type.

Each of the contact region 15 and the emitter region 12 is provided from one of the adjacent trench portions to the other. One or more contact regions 15 and one or more emitter regions 12 of the transistor portion 70 are provided to be exposed to the upper surface of the mesa portion 60 alternately along the extending direction of the trench portion.

In another example, in the mesa portion 60 of the transistor portion 70, the contact regions 15 and the emitter regions 12 may also be provided in a striped pattern along the extending direction. For example, the emitter region 12 is provided in a region in direct contact with the trench portion, and the contact region 15 is provided in a region sandwiched between the emitter regions 12.

In the transistor portion 70, the contact hole 54 is provided above each region of the contact region 15 and the emitter region 12. The contact hole 54 is not provided in a region which corresponds to the base region 14 or the well region 11.

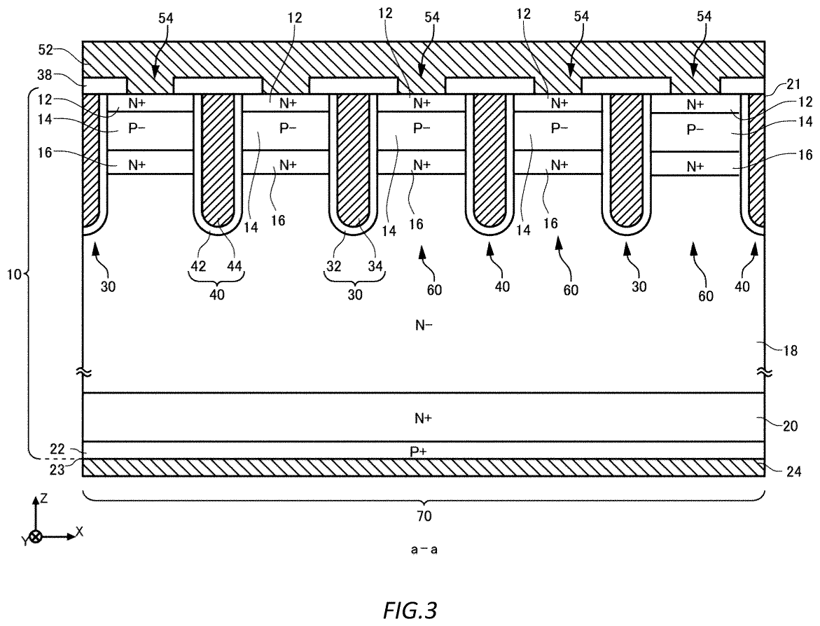

FIG. 3 is a diagram showing an example of a cross section a-a in FIG. 2. The cross section a-a lies on an XZ plane passing the emitter region 12. A semiconductor device 100 in this example includes a semiconductor substrate 10, an interlayer dielectric film 38, an emitter electrode 52, and a collector electrode 24 in the cross section. The emitter electrode 52 is provided on the upper surfaces of the interlayer dielectric film 38 and the semiconductor substrate 10.

The collector electrode 24 is provided on the back surface 23 of the semiconductor substrate 10. The collector electrode 24 is provided of a conductive material such as metal. As used herein, a direction in which the emitter electrode 52 and the collector electrode 24 are interconnected is referred to as depth direction. The depth direction of the present example refers to the Z axis direction.

The semiconductor substrate 10 may be a silicon substrate, may be a silicon carbide substrate, or may be a nitride semiconductor substrate such as gallium nitride, or the like. In the present example, the semiconductor substrate 10 is a silicon substrate. The base region 14 of a P− type is provided in the front surface 21 side of the semiconductor substrate 10 on the cross section.

On the cross section, in the front surface 21 side of the semiconductor substrate 10 in the transistor portion 70, the emitter region 12 of the N+ type, the base region 14 of the P− type and the accumulation region 16 of the N+ type are provided in this order from the front surface 21 side of the semiconductor substrate 10.

In the transistor portion 70, a drift region 18 of an N− type is provided below the accumulation region 16. The accumulation region 16 having a higher concentration than the drift region 18 is provided between the drift region 18 and the base region 14, so that it is possible to increase a carrier injection enhancement effect (IE effect), thereby reducing the on-voltage.

The accumulation region 16 of the present example is provided in each mesa portion 60 of the transistor portion 70. The accumulation region 16 may be provided so as to cover the entire lower surface of the base region 14 in each mesa portion 60. The buffer region 20 of the N+ type is provided below the drift region 18. In addition, a plurality of accumulation regions 16 may be provided in the depth direction.

The buffer region 20 is provided at the lower side of the drift region 18. The doping concentration of the buffer region 20 is higher than the doping concentration of the drift region 18. The buffer region 20 may function as a field stop layer to prevent a depletion layer, which expands from the lower surface of the base region 14, from reaching the P+ type collector region 22 and the N+ type cathode region 82. The collector region 22 of the P+ type is provided below the buffer region 20.

The one or more gate trench portions 40 and the one or more dummy trench portions 30 are provided in the front surface 21 side of the semiconductor substrate 10. Each trench portion is provided to extend from the front surface 21 of the semiconductor substrate 10 and penetrate through the base region 14 to reach the drift region 18. In a region in which at least any of the emitter region 12, the contact region 15 and the accumulation region 16 is provided, each trench portion penetrates through these regions to reach the drift region 18.

The trench portion penetrating the doping region is not limited to those manufactured in the order of forming the doping region and then forming the trench portion. The configuration of the trench portions penetrating the doping region also includes a configuration of forming the trench portions and then forming the doping region between the trench portions.

The gate trench portion 40 includes a gate dielectric film 42 and a gate conductive portion 44 provided in the front surface 21 side of the semiconductor substrate 10. The gate dielectric film 42 is provided to cover the inner wall of the gate trench portion 40. The gate dielectric film 42 may be formed by oxidizing or nitriding semiconductors on the inner wall of the gate trench portion 40. The gate conductive portion 44 is provided inside the gate dielectric film 42 in the gate trench portion 40. That is, the gate dielectric film 42 insulates the gate conductive portion 44 from the semiconductor substrate 10. The gate conductive portion 44 is formed of a conductive material such as polysilicon.

The gate conductive portion 44 includes a region opposite to the base region 14 intervening the gate dielectric film 42. The gate trench portion 40 in the cross section is covered by the interlayer dielectric film 38 on the front surface 21 of the semiconductor substrate 10. When a predetermined voltage is applied to the gate conductive portion 44, an inversion layer of electrons serving as a channel is formed on a surface layer in contact with the base region 14 with the gate trench.

The dummy trench portions 30 may have the same structure as the gate trench portions 40 in the cross section. The dummy trench portion 30 has a dummy trench, a dummy dielectric film 32, and a dummy conductive portion 34 which are provided on the front surface 21 side of the semiconductor substrate 10. The dummy dielectric film 32 is provided to cover an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44.

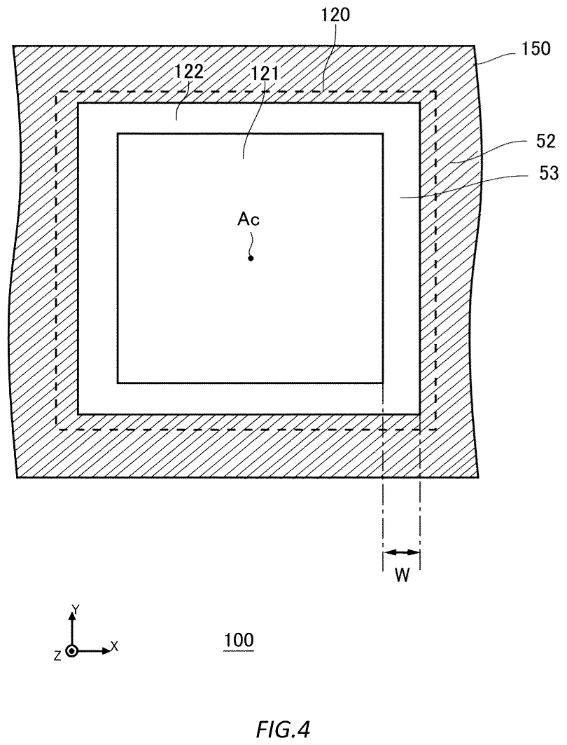

FIG. 4 is a diagram showing an example of the configurations of a first region 121 and a second region 122. The protective film 150 includes an opening portion corresponding to the exposed portion 53 on the emitter electrode 52. FIG. 4 shows a region in which the protective film 150 is provided hatched with diagonal lines. A lead frame is arranged on an upper surface of the exposed portion 53 and the emitter electrode 52 is electrically connected to the lead frame. A dimension of the exposed portion 53 is determined in accordance with a dimension of the arranged lead frame.

The first region 121 of the present example is a region including the center Ac of the active portion 120 in a region of the active portion 120 corresponding to the exposed portion 53. The center Ac of the active portion 120 is the geometric center of gravity of the active portion 120 in a top view. The lead frame is arranged to cover the first region 121. In a top view, a distance W between the first region 121 and an end portion of the exposed portion 53 is at least equal to or greater than 0 μm and equal to or smaller than 1500 μm.

The second region 122 is a region provided at an outer circumference of the first region 121 in a region of the active portion 120 corresponding to the exposed portion 53 and having a channel density lower than that of the first region 121. The second region 122 of the present example is provided to surround the entire outer circumference of the first region 121 in a top view and an outer circumferential end of the second region 122 is aligned with the end portion of the exposed portion 53. Note that, in another example, the second region 122 may be provided only in a part of a region of the outer circumference of the first region 121. An end portion of the lead frame is arranged in the second region 122.

During operation of the transistor portion 70, in the semiconductor substrate 10, a current generated in the vicinity of a region where the lead frame is arranged flows toward the lead frame. Therefore, in particular, the current crowding occurs in a region from the vicinity of an end portion of the lead frame to an end portion of a solder portion bonding the lead frame to the upper surface of the emitter electrode 52. In the region, an increase in the current density may cause a decrease in the turn off resistance and a decrease in reliability due to the heat generation.

According to the semiconductor device 100 of the present example, the channel density of the second region 122 where the end portion of the lead frame is arranged is lower than the channel density of the first region 121 right under the lead frame to suppress the current generation in the second region 122. This reduces the current crowding in the second region 122 during operation of the transistor portion 70 such that a decrease in the turn off resistance and a decrease in reliability due to the heat generation can be suppressed.

In a top view, an area of the first region 121 is equal to or greater than 0.5 times and equal to or smaller than ten times an area of the second region 122. The area ratio is within this range such that a sufficient amount of currents can be secured across the entire semiconductor device 100 while reducing the current crowding in the second region 122.

The outer circumferential end of the second region 122 of the present example is aligned with the end portion of the exposed portion 53. However, in another example, it may be inside the end portion of the exposed portion 53. In this case, the outside of the second region 122 may include the front surface device structure similar to that of the first region 121. This can reduce the current crowding in the second region 122 while facilitating the current generation across the entire active portion 120.

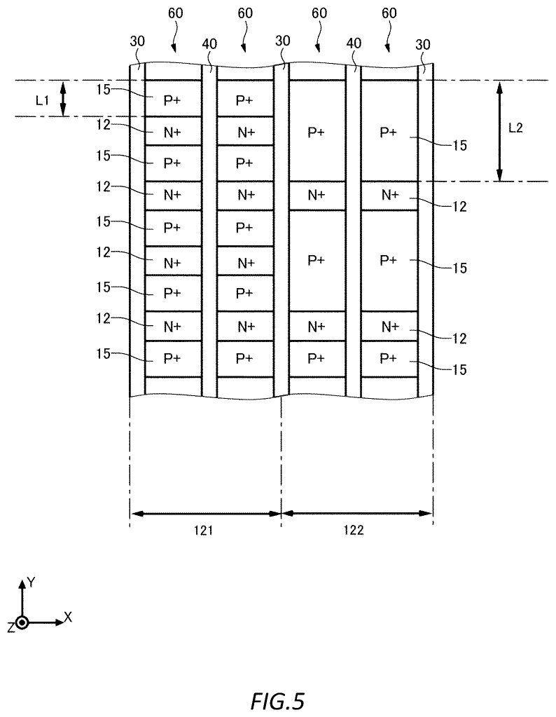

FIG. 5 is a top view showing an example of the mesa portion 60. The active portion 120 of the present example includes the transistor portion 70 as shown in FIG. 2 and FIG. 3. The emitter regions 12 and the contact regions 15 are provided alternately in the mesa portion 60 of the transistor portion 70 in the trench extending direction.

In the present example, the channel density of the mesa portion 60 of the transistor portion 70 in the second region 122 is smaller than that of the mesa portion 60 of the transistor portion 70 in the first region 121. The channel density in the transistor portion 70 is determined depending on a ratio of the contact regions 15 and the emitter regions 12 in the trench extending direction. In a top view, a ratio of the emitter regions 12 to the contact regions 15 in the mesa portion 60 of the transistor portion 70 in the first region 121 is greater than a ratio of the emitter regions 12 to the contact regions 15 in the mesa portion 60 of the transistor portion 70 in the second region 122.

In a top view, a length L2 of the contact region 15 provided in the mesa portion 60 of the transistor portion 70 in the second region 122 in the trench extending direction is greater than a length L1 of the contact region 15 provided in the mesa portion 60 of the transistor portion 70 in the first region 121 in the trench extending direction.

In a top view, the emitter regions 12 of the transistor portion 70 in the second region 122 may be provided to correspond to the emitter regions 12 of the transistor portion 70 in the first region 121 in the trench array direction, and the emitter regions 12 of the transistor portion 70 in the first region 121 may be provided to correspond to any of the emitter regions 12 or the contact regions 15 of the transistor portion 70 in the second region 122 in the trench array direction.

While the emitter regions 12 of the present example are provided to extend across a plurality of mesa portions 60 of the first region 121 in the trench array direction, some emitter regions 12 also extend across a plurality of mesa portions 60 in the second region 122 and other emitter regions 12 do not extend to the second region 122 and terminate within the first region 121.

That is, some emitter regions 12 are thinned out in the second region 122, as compared to the first region 121, thereby reducing the channel density. For example, the channel density of the mesa portion 60 of the transistor portion 70 in the second region 122 is equal to or smaller than 50% of the channel density of the mesa portion 60 of the transistor portion 70 in the first region 121. This suppresses the current generation in the second region 122.

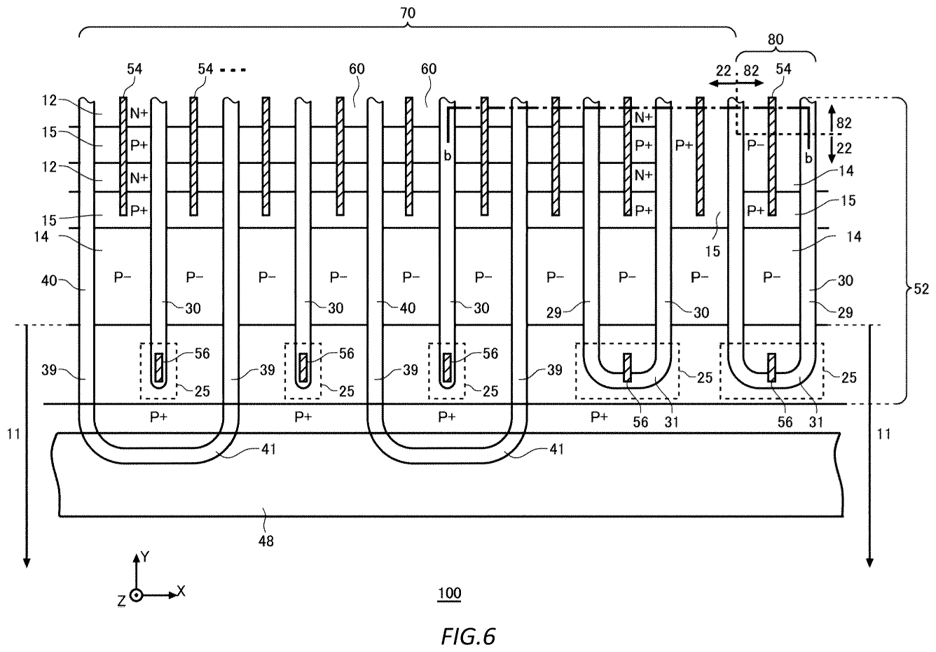

FIG. 6 is another example of an enlarged view of the active portion 120. The active portion 120 of the present example includes the transistor portions 70 and the diode portions 80 provided alternately in the trench array direction. Here, a difference from the example of FIG. 2 including only the transistor portion 70 will mainly be described and the same elements will not be described.

In the diode portion 80, the cathode region 82 of the N+ type is provided in a region in direct contact with the back surface of the semiconductor substrate 10. In FIG. 6, the region provided with the cathode region 82 is illustrated with a dotted line. In the active portion 120, a region not provided with the cathode region 82 on the back surface side of the semiconductor substrate 10 may be provided with the collector region of the P+ type.

In the active portion 120, a projection region overlapping with the cathode region 82 in the Z axis direction is defined as the diode portion 80. That is, a projection region where the cathode region 82 is projected onto the front surface of the semiconductor substrate 10 in a direction perpendicular to the back surface of the semiconductor substrate 10 is defined as the diode portion 80. In addition, an extension region of the projection region to the well region in the Y axis direction may also be defined as the diode portion 80. In addition, in the active portion 120, a projection region where the collector region 22 is projected onto the front surface of the semiconductor substrate 10 in a direction perpendicular to the back surface of the semiconductor substrate 10 and where predetermined unit configurations including the emitter regions 12 and the contact regions 15 are regularly arranged is defined as the transistor portion 70.

While FIG. 6 shows one mesa portion 60 of the diode portion 80, the diode portion 80 may include a plurality of mesa portions 60 in the X axis direction. The mesa portion 60 of the diode portion 80 is provided with the contact region 15 and the base region 14 exposed to the front surface of the semiconductor substrate 10 in a region not provided with the contact region 15. The emitter region 12 may not be provided in the mesa portion 60 of the diode portion 80. In the mesa portion 60 adjacent to the transistor portion 70, the contact region 15 is provided on the front surface of the semiconductor substrate 10. The contact hole 54 is provided above the contact region 15 and the base region 14.

In the diode portion 80, one or more dummy trench portions 30 are arrayed at a predetermined interval along the X axis direction. The dummy trench portion 30 of the diode portion 80 may include an extending portion 29 and an edge portion 31. The edge portion 31 and the extending portion 29 have shapes similar to the edge portion 41 and the extending portion 39, respectively. The dummy trench portion 30 having the edge portion 31 and the dummy trench portion 30 in a straight shape may have the same length in the extending direction.

In the transistor portion 70, an intermediate region not provided with the emitter region on a surface may be provided at a boundary adjacent to the diode portion 80. The mesa portion 60 of the intermediate region may be provided with the contact region 15 across a larger area than in the mesa portion 60 of the transistor portion 70. In addition, in the transistor portion 70, a plurality of dummy trench portions 30 may be arrayed continuously at a portion adjacent to the intermediate region. The dummy trench portion 30 provided at the portion adjacent to the intermediate region may also include the extending portions 29 and the edge portion 31.

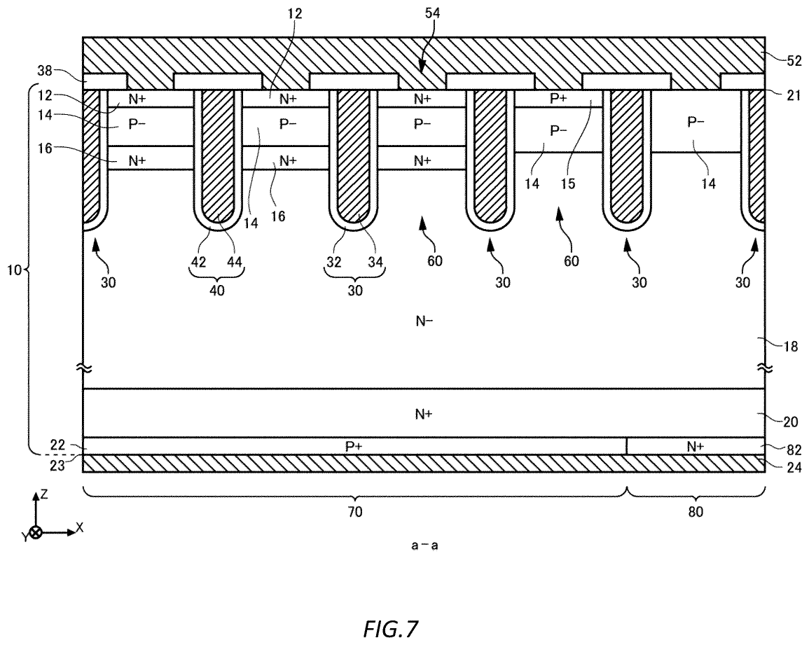

FIG. 7 is a diagram showing an example of a cross section b-b in FIG. 6. On the cross section, the base region 14 is provided on the front surface 21 side of the semiconductor substrate 10 in the diode portion 80. The diode portion 80 of the present example is not provided with the accumulation region 16. Alternatively, in another example, the diode portion 80 may be provided with an accumulation region 16. In addition, a plurality of accumulation regions 16 may be provided in the depth direction.

In the diode portion 80, the drift region 18 is provided below the base region 14. In the diode portion 80, the cathode region 82 of the N+ type is provided below the buffer region 20.

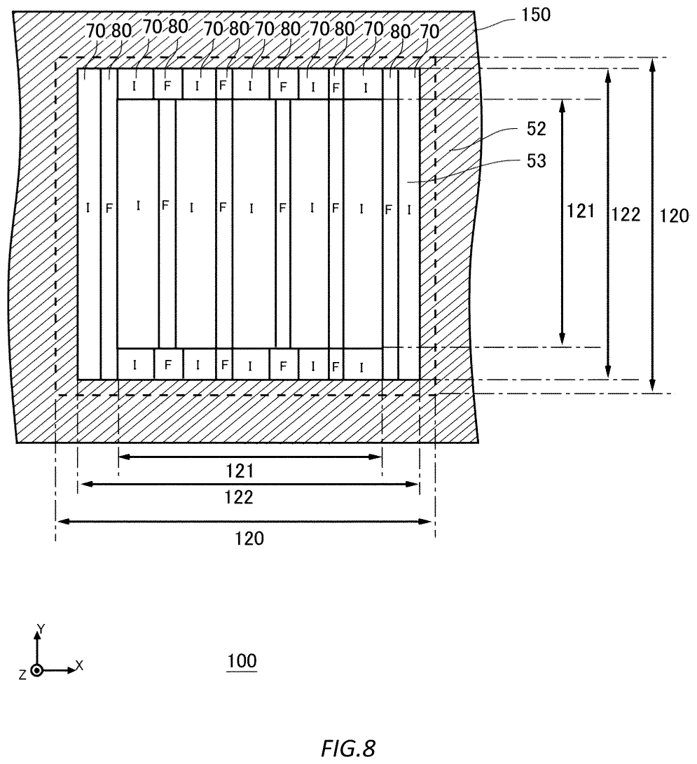

FIG. 8 is a diagram showing an exemplary arrangement of the transistor portion 70 and the diode portion 80. FIG. 8 shows the transistor portion 70 with a symbol of I and the diode portion 80 with a symbol of F. In the active portion 120 of the present example, the transistor portions 70 and the diode portions 80 shown in FIG. 6 and FIG. 7 are arrayed alternately in the X axis direction. In a top view, an area of each transistor portion 70 is greater than an area of each diode portion 80.

In a top view, a ratio of the diode portions 80 to the transistor portions 70 in the second region 122 is greater than a ratio of the diode portions 80 to the transistor portions 70 in the first region 121. In the first region 121 of the present example, a width of the transistor portion 70 is greater than a width of the diode portion 80 in the X axis direction. In the second region 122 of the present example, some diode portions 80 have the same width as that of the diode portion 80 in the first region 121, and a width of other diode portions 80 is greater than a width of the diode portion 80 in the first region 121.

In this manner, in the second region 122, an area ratio of the diode portions 80 to the transistor portions 70 is higher than that of the first region 121 so that the channel density is lower than that of the first region 121. This suppresses the current generation in the second region 122.

Note that, in a top view, even in the second region 122 having a higher area ratio of the diode portions 80, an area of the transistor portions 70 is greater than an area of the diode portions 80. This can secure a sufficient amount of currents across the entire semiconductor device 100 while reducing the current crowding in the second region 122.

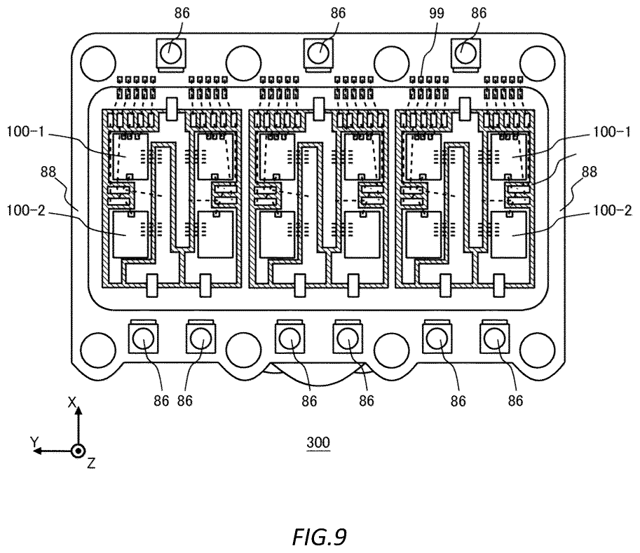

FIG. 9 is a top view showing an example of a semiconductor module 300 according to an exemplary embodiment. The semiconductor module 300 includes a first semiconductor device 100-1 and a second semiconductor device 100-2. Each of the first semiconductor device 100-1 and the second semiconductor device 100-2 is any of the semiconductor devices 100 shown in FIG. 1 to FIG. 8. The semiconductor module 300 may include multiple pairs of the first semiconductor device 100-1 and the second semiconductor device 100-2.

The semiconductor module 300 of the present example includes a housing 88. The housing 88 accommodates each semiconductor device 100. Inside the housing 88, a cooling agent flows to cool the semiconductor device 100. The semiconductor module 300 further includes at least one of a temperature sensor and a current sensor.

The housing 88 includes main terminals 86 and control terminals 99. At least some of the main terminals 86 are electrically connected to the emitter electrode 52 of the semiconductor device 100. At least some of the control terminals 99 are electrically connected to the pad 50 of the semiconductor device 100. In addition, at least some of the control terminals 99 are electrically connected to sensors of the semiconductor device 100.

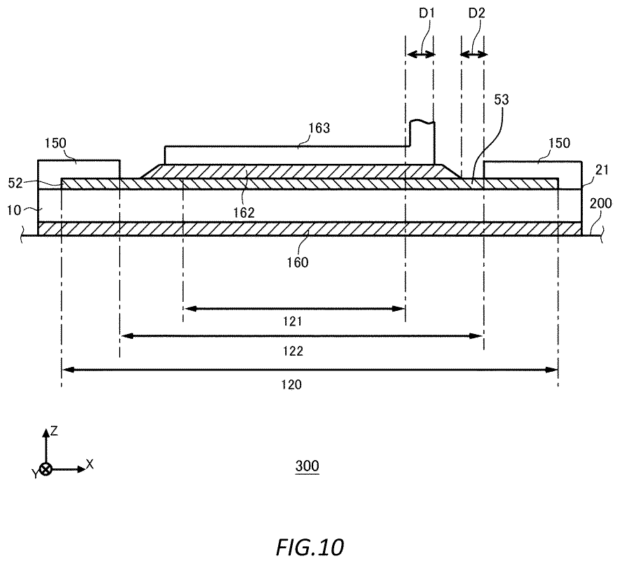

FIG. 10 is a side view of the semiconductor substrate 10 mounted on a packaging substrate 200. In FIG. 10, the collector electrode 24, the interlayer dielectric film 38 and the like are omitted. The semiconductor substrate 10 is fixed onto the packaging substrate 200 by a connecting portion 160 such as a solder. A solder portion 162 and a lead frame 163 provided on the solder portion 162 and electrically connected to the emitter electrode 52 are provided above the exposed portion 53 of the emitter electrode 52. In addition, a protective film 150 including an opening portion corresponding to the exposed portion 53 is provided above the front surface 21 of the semiconductor substrate 10 and the emitter electrode 52.

As shown in FIG. 10, the solder portion 162 has a cross section of a flared shape to increase a bonding strength with the emitter electrode 52. The protective film 150 is provided to prevent the solder portion 162 from extending to the pad 50, the pad region or the like provided around the emitter electrode 52.

In addition, the protective film 150 restricts an extension range of the solder portion 162 to suppress the deviation of the position of the solder portion 162. The deviation of the position of the solder portion 162 causes the displacement of the center of gravity of the semiconductor device 100 so that the semiconductor substrate 10 is fixed in the inclined state in the process of mounting the semiconductor substrate 10 on the packaging substrate 200 the connecting portion 160. The protective film 150 is provided to suppress the deviation of the position of the solder portion 162 such that the inclination of the semiconductor substrate 10 can be suppressed when mounted.

As described above, during operation of the transistor portion 70, in the semiconductor substrate 10, a current generated in the vicinity of a region where the lead frame 163 is arranged flow toward the lead frame 163. Therefore, in particular, the current crowding occurs in a region from the vicinity of the end portion of the lead frame 163 to the end portion of the solder portion 162. In the region, an increase in the current density may cause a decrease in the turn off resistance and a decrease in reliability due to the heat generation.

Therefore, in the present example, the region from the vicinity of the end portion of the lead frame 163 to the end portion of the solder portion 162 where the current crowding occurs during operation the transistor portion 70 is arranged in the second region 122 having a lower channel density. A boundary between the first region 121 and the second region 122 of the present example is provided inside the end portion of the lead frame 163. A distance D1 between the boundary between the first region 121 and the second region 122 and the end portion of the lead frame 163 is equal to or greater than 400 μm and equal to or smaller than 800 μm.

In addition, the outer circumferential end of the second region 122 of the present example is provided outside the end portion of the solder portion 162. A distance D2 between the outer circumferential end of the second region 122 and the end portion of the solder portion 162 is equal to or greater than 0 μm and equal to or smaller than 1500 μm. In this manner, in the present example, the current generation is suppressed in the second region 122 such that the current crowding is reduced in the second region 122 during operation of the transistor portion 70 to suppress a decrease in the turn off resistance and a decrease in reliability due to the heat generation.

Note that, in FIG. 1 to FIG. 10, the examples have been described where the first region 121 and the second region 122 are provided to correspond to the lead frame in the exposed portion 53 which is a region including the center Ac of the active portion. However, if the additional active portions are provided above and below the pad 50 and the pad region (in the +Y axis direction and the −Y axis direction), the exposed portions 53 where the lead frames are to be arranged may also be provided in the extended emitter electrodes 52 provided above the additional active portions, and each of the exposed portions 53 may be provided with the first region 121 and the second region 122.

While the present invention has been described with the embodiments, the technical scope of the present invention is not limited to the above-described embodiments. It is apparent to persons skilled in the art that various alterations or improvements can be added to the above-described embodiments. It is also apparent from the description of the claims that embodiments added with such alterations or improvements can be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10: semiconductor substrate, 11: well region, 12: emitter region, 14: base region, 15: contact region, 16: accumulation region, 18: drift region, 20: buffer region, 21: front surface, 22: collector region, 23: back surface, 24: collector electrode, 25: connecting portion, 29: extending portion, 30: dummy trench portion, 31: edge portion, 32: dummy dielectric film, 34: dummy conductive portion, 38: interlayer dielectric film, 39: extending portion, 40: gate trench portion, 41: edge portion, 42: gate dielectric film, 44: gate conductive portion, 48: gate runner, 50: pad, 52: emitter electrode, 53: exposed portion, 54: contact hole, 56: contact hole, 60: mesa portion, 70: transistor portion, 80: diode portion, 82: cathode region, 86: main terminal, 88: housing, 99: control terminal, 100: semiconductor device, 102: end side, 120: active portion, 121: first region, 122: second region, 150: protective film, 160: connecting portion, 162: solder portion, 163: lead frame, 172: current detection pad, 174: anode pad, 176: cathode pad, 200: packaging substrate, 300: semiconductor module

What is claimed is:

1. A semiconductor device, comprising:
a semiconductor substrate including an active portion provided with a transistor portion;
an emitter electrode provided above a front surface of the semiconductor substrate; and
a protective film provided above the emitter electrode,
wherein the active portion includes: an emitter region of a first conductivity type provided on the front surface of the semiconductor substrate; a contact region of a second conductivity type; and a plurality of trench portions,
wherein the emitter electrode includes an exposed portion not covered by the protective film, and
wherein the active portion includes: in a region in which the exposed portion is provided, a first region; and a second region provided at an outer circumference of the first region and having a channel density lower than that of the first region.

2. The semiconductor device according to claim 1, wherein
in a top view of the semiconductor substrate, the second region is provided to surround the entire outer circumference of the first region.

3. The semiconductor device according to claim 1, wherein
in a top view of the semiconductor substrate, an area of the first region is equal to or greater than 0.5 times and equal to or smaller than ten times an area of the second region.

4. The semiconductor device according to claim 1, wherein
in a top view of the semiconductor substrate, the first region is spaced apart from an end portion of the exposed portion by at least equal to or greater than 0 μm and equal to or smaller than 1500 μm.

5. The semiconductor device according to claim 1, wherein
a channel density of a mesa portion of the transistor portion in the second region is smaller than a channel density of a mesa portion of the transistor portion in the first region.

6. The semiconductor device according to claim 1, wherein
the emitter region and the contact region are provided alternately in a trench extending direction in a mesa portion of the transistor portion, and
in a top view of the semiconductor substrate, a ratio of the emitter region to the contact region in a mesa portion of the transistor portion in the first region is greater than a ratio of the emitter region to the contact region in a mesa portion of the transistor portion in the second region.

7. The semiconductor device according to claim 6, wherein
in a top view of the semiconductor substrate, a length of the contact region provided in a mesa portion of the transistor portion in the second region in a trench extending direction is greater than a length of the contact region provided in a mesa portion of the transistor portion in the first region in the trench extending direction.

8. The semiconductor device according to claim 7, wherein
in a top view of the semiconductor substrate, the emitter region of the transistor portion in the second region is provided to correspond to the emitter region of the transistor portion in the first region in a trench array direction, and
in a top view of the semiconductor substrate, the emitter region of the transistor portion in the first region is provided to correspond to either the emitter region or the contact region of the transistor portion in the second region in the trench array direction.

9. The semiconductor device according to claim 5, wherein
a channel density of a mesa portion of the transistor portion in the second region is equal to or smaller than 50% of a channel density of a mesa portion of the transistor portion in the first region.

10. The semiconductor device according to claim 1, wherein
the active portion includes a diode portion provided alternately with the transistor portion in a trench array direction, and
in a top view of the semiconductor substrate, a ratio of the diode portion to the transistor portion in the second region is greater than a ratio of the diode portion to the transistor portion in the first region.

11. The semiconductor device according to claim 10, wherein
in a top view of the semiconductor substrate, in the second region, an area of the transistor portion is greater than an area of the diode portion.

12. A semiconductor module comprising the semiconductor device according to claim 1.

13. The semiconductor module according to claim 12, comprising:
a solder portion provided above the emitter electrode; and
a lead frame provided on the solder portion and electrically connected to the emitter electrode.

14. The semiconductor module according to claim 13, wherein
in a top view of the semiconductor substrate, a boundary between the first region and the second region is provided inside an end portion of the lead frame.

15. The semiconductor module according to claim 14, wherein
a distance between a boundary between the first region and the second region and the end portion of the lead frame is equal to or greater than 400 μm and equal to or smaller than 800 μm.

16. The semiconductor module according to claim 14, wherein
an outer circumferential end of the second region is provided outside an end portion of the solder portion.

17. The semiconductor module according to claim 16, wherein
a distance between the outer circumferential end of the second region and the end portion of the solder portion is equal to or greater than 0 μm and equal to or smaller than 1500 μm.

18. The semiconductor device according to claim 1, wherein
each of the emitter region and the contact region is provided to extend from one trench portion to an adjacent trench portion of the plurality of trench portions in a trench array direction, and
the emitter region and the contact region are provided alternately in a trench extending direction, and the contact region provided in a mesa portion of the transistor portion in the second region includes: a first contact region; and a second contact region having a length in the trench extending direction different from that of the first contact region.

19. The semiconductor device according to claim 1, wherein
the emitter region and the contact region are provided alternately in a trench extending direction in a mesa portion of the transistor portion, and
in a top view of the semiconductor substrate, the emitter region of the transistor portion in the second region is a region provided by the emitter region of the transistor portion in the first region extending to the transistor portion in the second region in a trench array direction.

20. The semiconductor device according to claim 19, wherein
in a top view of the semiconductor substrate, at least one emitter region of the transistor portion in the first region terminates within the first region in a trench array direction, and
the emitter region terminating within the first region and the contact region of the transistor portion in the second region are positioned next to each other in a trench array direction with the trench portion interposed therebetween.
